(19) United States
(12) Patent Application Publication
(10) Pub. No.: US 2006/0131629 A1
(43) Pub. Date: Jun. 22, 2006

(54) Magnetic random access memory having magnetoresistive element with nonmagnetic metal layer

(76) Inventors: Yoshiaki Fukuzumi, Yokohama-shi (JP); Toshihiko Nagase, Sagamihara-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/192,020

(22) Filed: Jul. 29, 2005

(30) Foreign Application Priority Data
Dec. 22, 2004 (JP) 2004-371735

(51) Int. Cl. H01L 29/94

(52) U.S. Cl. 257/295

(57) ABSTRACT

A magnetic random access memory in which a plurality of magnetoresistive elements are laid out in an array, the magnetoresistive element includes a lower ferromagnetic layer, an upper ferromagnetic layer which has a planar shape smaller than a planar shape of the lower ferromagnetic layer, a first nonmagnetic insulating layer which is formed between the lower ferromagnetic layer and the upper ferromagnetic layer, and a first nonmagnetic metal layer which is formed between the first nonmagnetic insulating layer and the upper ferromagnetic layer.

### CROSS-REFERENCE TO RELATED APPLICATIONS

This application is based upon and claims the benefit of priority from prior Japanese Patent Application No. 2004-371735, filed Dec. 22, 2004, the entire contents of which are incorporated herein by reference.

### BACKGROUND OF THE INVENTION

1. Field of the Invention

The present invention relates to a magnetic random access memory having a magnetoresistive element with a nonmagnetic metal layer.

2. Description of the Related Art

In recent years, magnetic random access memories (MRAMs) using the tunneling magnetoresistance (TMR) effect have been proposed as a kind of semiconductor memory. A memory cell of the magnetic random access memory comprises a magnetic tunnel junction (MTJ) element having a fixed layer, recording layer, and tunnel barrier layer sandwiched between them.

To increase the operation ratio of such a magnetic random access memory, shift adjustment of the asteroid characteristic and improvement of the element short-circuit ratio are important.

To improve the element short-circuit ratio, a so-called barrier stop process can effectively be introduced. In the barrier stop process, after the materials of the fixed layer, tunnel barrier layer, and recording layer are deposited, etching (e.g., milling) of the recording layer is stopped on the upper surface of the tunnel barrier layer. In the current barrier stop process, however, the surface of the fixed layer is damaged through the tunnel barrier layer. As a result, the nature of the magnetic material of the fixed layer changes, and irregular field leakage occurs.

For shift adjustment of the asteroid characteristic, Neel coupling and the field leakage from the ends of the fixed layer must be canceled. However, since irregular field leakage occurs from the surface of the fixed layer degraded by the barrier stop process, as described above, shift adjustment of the asteroid characteristic cannot easily be executed, resulting in a variation in magnetic characteristic.

Conventionally, introduction of the so-called barrier stop process and shift adjustment of the asteroid characteristic cannot be executed simultaneously, as described above. Hence, it is difficult to reduce the variation in magnetic characteristic while suppressing the short circuit in the element.

Examples of prior-art reference information relevant to the present invention are Jpn. Pat. Appln. KOKAI Publication Nos. 2004-179652 and 2002-324929 and U.S. Pre-Grant Publication No. 2004/0063223A1.

### BRIEF SUMMARY OF THE INVENTION

A magnetic random access memory according to an aspect of the present invention is a magnetic random access memory in which a plurality of magnetoresistive elements are laid out in an array, the magnetoresistive element comprising a lower ferromagnetic layer, an upper ferromagnetic layer which has a planar shape smaller than a planar shape of the lower ferromagnetic layer, a first nonmagnetic insulating layer which is formed between the lower ferromagnetic layer and the upper ferromagnetic layer, and a first nonmagnetic metal layer which is formed between the first nonmagnetic insulating layer and the upper ferromagnetic layer.

### BRIEF DESCRIPTION OF THE SEVERAL VIEWS OF THE DRAWING

FIGS. 1A and 1B are views showing an MTJ element according to the first embodiment of the present invention, in which FIG. 1A is a plan view, and FIG. 1B is a sectional view taken along a line IB-IB in FIG. 1A;

FIGS. 2A and 2B are views showing an MTJ element according to the second embodiment of the present invention, in which FIG. 2A is a plan view, and FIG. 2B is a sectional view taken along a line IIB-IIB in FIG. 2A;

FIGS. 3A to 3C are sectional views showing steps in manufacturing the MTJ element according to the second embodiment of the present invention;

FIGS. 4A and 4B are views showing an MTJ element according to the third embodiment of the present invention, in which FIG. 4A is a plan view, and FIG. 4B is a sectional view taken along a line IVB-IVB in FIG. 4A;

FIGS. 5A and 5B are views showing an MTJ element according to the fourth embodiment of the present invention, in which FIG. 5A is a plan view, and FIG. 5B is a sectional view taken along a line VB-VB in FIG. 5A;

FIGS. 6A and 6B are views showing an MTJ element according to the fifth embodiment of the present invention, in which FIG. 6A is a plan view, and FIG. 6B is a sectional view taken along a line VIB-VIB in FIG. 6A;

FIGS. 7A, 7B, 8A, and 8B are sectional views showing steps in manufacturing the MTJ element according to the fifth embodiment of the present invention;

FIGS. 9A and 9B are views showing an MTJ element according to the sixth embodiment of the present invention, in which FIG. 9A is a plan view, and FIG. 9B is a sectional view taken along a line IXB-IXB in FIG. 9A;

FIGS. 10A and 10B are views showing a select transistor memory cell of a magnetic random access memory according to the seventh embodiment of the present invention, in which FIG. 10A is a circuit diagram showing a memory cell array, and FIG. 10B is a sectional view showing one cell;

FIGS. 11A and 11B are views showing a select diode memory cell of the magnetic random access memory according to the seventh embodiment of the present invention, in which FIG. 11A is a circuit diagram showing a memory cell array, and FIG. 11B is a sectional view showing one cell;

FIGS. 12A and 12B are views showing a cross-point memory cell of the magnetic random access memory according to the seventh embodiment of the present invention, in which FIG. 12A is a circuit diagram showing a memory cell array, and FIG. 12B is a sectional view showing one cell; and

FIG. 13 is a plan view showing a toggle memory cell of the magnetic random access memory according to the seventh embodiment of the present invention.

### DETAILED DESCRIPTION OF THE INVENTION

Preferred embodiments of the present invention will be described below with reference to the accompanying drawing. The same reference numerals denote the same parts throughout the drawing.

### First Embodiment

In the first embodiment, a nonmagnetic metal layer is formed under a nonmagnetic insulating layer which functions as a tunnel barrier in an MTJ (Magnetic Tunnel Junction) element as a magnetoresistive element.

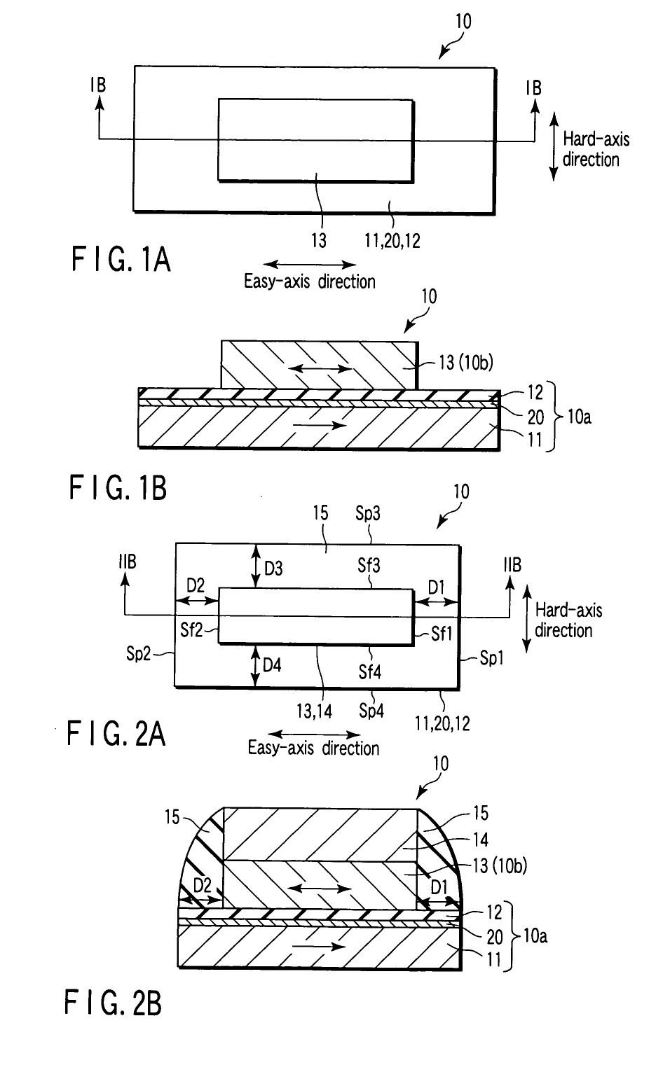

FIGS. 1A and 1B are plan and sectional views, respectively, showing an MTJ element according to the first embodiment of the present invention. The MTJ element according to the first embodiment will be described below.

As shown in FIGS. 1A and 1B, an MTJ element 10 has a fixed layer (pinned layer) 11 serving as a lower ferromagnetic layer whose magnetization direction is fixed, a recording layer (free layer) 13 serving as an upper ferromagnetic layer whose magnetization direction is reversed, and a nonmagnetic insulating layer (e.g., tunnel barrier layer) 12 sandwiched between the fixed layer 11 and the recording layer 13. In addition, a nonmagnetic metal layer 20 is formed between the fixed layer 11 and the nonmagnetic insulating layer 12.

The MTJ element 10 has a first portion 10a including the fixed layer 11, nonmagnetic metal layer 20, and nonmagnetic insulating layer 12, and a second portion 10b including the recording layer 13. The planar shapes of the fixed layer 11, nonmagnetic metal layer 20, and nonmagnetic insulating layer 12 included in the first portion 10a are almost the same. Their side surfaces coincide with each other. The planar shape of the first portion 10a is larger than that of the second portion 10b (recording layer 13).

The nonmagnetic metal layer 20 is preferably made of a material containing, e.g., Pt, Ir, or Cu. The material may contain a small amount of a nonmagnetic material such as Ta or Ru. Pt is an especially preferable material for the nonmagnetic metal layer 20 because it is highly resistant to oxidation. The nonmagnetic metal layer 20 is formed from not a magnetic material but a nonmagnetic material. Even if the nonmagnetic metal layer 20 is damaged by milling in the so-called barrier stop process, the magnetic function is not lost or disturbed because the nonmagnetic metal layer 20 is made of a nonmagnetic material. Hence, no random field leakage occurs.

The nonmagnetic metal layer 20 preferably has (a) oxidation resistance, (b) oxygen barrier effect, (c) low sputtering yield, (d) high magnetoresistive (MR) ratio, and (e) wettability.

(a) The oxidation resistance is required due to the following reason. If the nonmagnetic insulating layer 12 is made of, e.g., alumina (AlO), this alumina is often formed by depositing aluminum and oxidizing it. When aluminum is oxidized, the nonmagnetic metal layer 20 may also be oxidized. The fixed layer 11 (or recording layer 13) under the nonmagnetic metal layer 20 is often formed from a material (e.g., CoFe or NiFe) easy to be oxidized. When the nonmagnetic metal layer 20 is oxidized, the fixed layer 11 may also be oxidized. To prevent oxidation of the fixed layer 11, the nonmagnetic metal layer 20 preferably has oxidation resistance. When a material (material with a low oxidation rate) such as Pt or Ir harder to be oxidized (more resistant to oxidation) than the nonmagnetic insulating layer (e.g., alumina) 12 is used for the nonmagnetic metal layer 20, only aluminum can easily selectively be oxidized. Uniform alumina can be formed in the direction of thickness, and any variation in tunnel resistance can be suppressed. For this reason, the yield and reliability of the MTJ element 10 can be increased. In addition, the nonmagnetic metal layer 20 preferably contains a material of higher resistance to oxidation than the lower ferromagnetic layer (fixed layer 11 in FIG. 1B) under the nonmagnetic metal layer 20.

(b) The oxygen barrier effect is necessary due to the following reason. If the nonmagnetic insulating layer 12 is made of, e.g., alumina, oxygen may enter the fixed layer 11 (or recording layer 13) through the nonmagnetic metal layer 20 in the aluminum oxidation step to be oxidized the fixed layer 11. To prevent oxidation of the fixed layer 11, the nonmagnetic metal layer 20 preferably has a characteristic not allowing oxygen to pass.

(c) The low sputtering yield is demanded due to the following reason. In milling in the so-called barrier stop process, the etching rate generally becomes low in the nonmagnetic insulating layer 12. For this reason, etching stops at the nonmagnetic insulating layer 12. However, overetching may occur if etching does not stop at the nonmagnetic insulating layer 12. To prevent etching of the fixed layer 11, a material of high etching resistance is preferably used for the nonmagnetic metal layer 20. Milling is performed by using, e.g., argon. Hence, the nonmagnetic metal layer 20 preferably contains a material made of atoms heavier than argon. In addition, the nonmagnetic metal layer 20 preferably contains a material made of atoms heavier than the lower ferromagnetic layer (fixed layer 11 in FIG. 1B).

(d) The high MR ratio is required due to the following reason. When the nonmagnetic metal layer 20 is formed in the MTJ element 10, the MR ratio generally decreases to some extent as compared to an element having no nonmagnetic metal layer 20. To prevent this, a material that does not decrease the MR ratio as much as possible is preferably used. Examples of such a material are Pt, Ir, and Cu. Ta and Ru may also be included. Pt or Ir is more preferable because Cu is readily oxidized.

(e) The wettability is necessary due to the following reason. If the nonmagnetic insulating layer 12 is made of, e.g., alumina, it is formed by depositing aluminum and oxidizing it instead of directly sputtering alumina. This is because it is difficult to form alumina on the material (e.g., CoFe) of the fixed layer 11 by sputtering, since the alumina film surface becomes uneven. To prevent this, the nonmagnetic metal layer 20 preferably has wettability to tightly contact alumina.

The thickness of the nonmagnetic metal layer 20 is preferably, e.g., 0.3 to 2.0 nm. The damage depth caused by current milling is about 0.3 nm. The minimum necessary thickness to prevent damage of the fixed layer 11 is preferably 0.3 nm or more. If the thickness, however, is larger than 2.0 nm, the MR ratio may decrease. Hence, the thickness is preferably 2.0 nm or less. The thickness of the nonmagnetic metal layer 20 is more preferably about 1 nm.

The following ferromagnetic materials can be used for the fixed layer 11 and recording layer 13. For example, Fe, Co, Ni, a layered film thereof, an alloy thereof, magnetite having a high spin polarizability, an oxide such as CrO₂ or RXMnO_{3-y} (R: rare earth, X: Ca, Ba, or Sr), or a Heusler alloy such as NiMnSb or PtMnSb is preferably used. The magnetic materials may contain a small amount of nonmagnetic element such as Ag, Cu, Au, Al, Mg, Si, Bi, Ta, B, C, O, N, Pd, Pt, Zr, Ir, W, Mo, or Nb as long as the ferromagnetism is not lost.

For the nonmagnetic insulating layer 12, various dielectric materials such as Al₂O₃, SiO₂, MgO, AlN, Bi₂O₃, MgF₂, CaF₂, SrTiO₂, or AlLaO₃ can be used. These dielectric materials may contain oxygen, nitrogen, or fluorine defects.

According to the first embodiment, any short circuit in the element can be suppressed, and the variation in magnetic characteristic can be reduced due to the following reasons.

When the planar shape of the recording layer 13 serving as the upper ferromagnetic layer is made smaller than that of the fixed layer 11 serving as the lower ferromagnetic layer by the so-called barrier stop process, the ends of the recording layer 13 and those of the fixed layer 11 can be spaced apart from each other. Since this suppresses the contact between the recording layer 13 and the fixed layer 11, a short circuit in the element can be suppressed. Accordingly, the yield of the element can be increased.

The nonmagnetic metal layer 20 is formed under the nonmagnetic insulating layer 12. Even when the recording layer 13 is fabricated by, e.g., milling in the so-called barrier stop process, and the nonmagnetic insulating layer 12 is damaged by milling, the nonmagnetic metal layer 20 can absorb the damage. That is, even when the nonmagnetic metal layer 20 is damaged by milling, no magnetic adverse effect is generated because the nonmagnetic metal layer 20 is made of a nonmagnetic material. Since the fixed layer 11 serving as the lower ferromagnetic layer can be suppressed from being damaged, no random field leakage occurs from the damage surface of the fixed layer 11. Hence, the shift amount of the asteroid characteristic can easily be adjusted, and the variation in magnetic characteristic can be reduced.

### Second Embodiment

The second embodiment is a modification to the first embodiment, in which a sidewall layer is formed on the side surfaces of the upper ferromagnetic layer to form the lower ferromagnetic layer in a self-aligned manner with respect to the upper ferromagnetic layer.

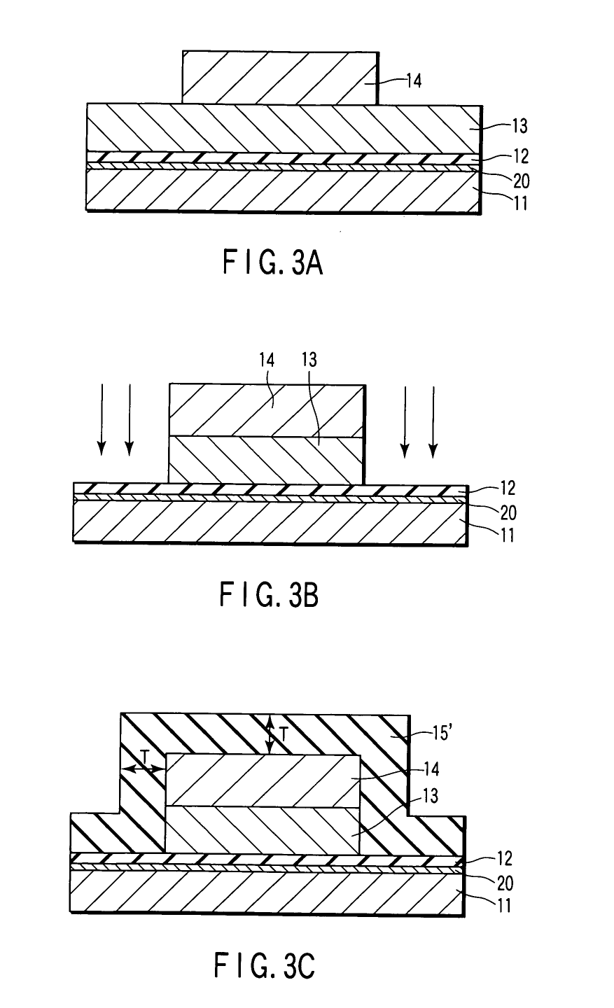

FIGS. 2A and 2B are plan and sectional views, respectively, showing an MTJ element according to the second embodiment of the present invention. FIGS. 3A to 3C are sectional views showing steps in manufacturing the MTJ element according to the second embodiment of the present invention. The MTJ element according to the second embodiment will be described below.

As shown in FIGS. 2A and 2B, the second embodiment is different from the first embodiment in that a fixed layer 11 is fabricated in a self-aligned manner with respect to a recording layer 13 by using a sidewall layer 15. More specifically, an MTJ element 10 according to the second embodiment is formed in the following way.

First, as shown in FIG. 3A, the fixed layer 11, nonmagnetic metal layer 20, nonmagnetic insulating layer 12, and recording layer 13 are sequentially deposited. A hard mask layer 14 having a desired shape is formed on the recording layer 13. Examples of the material of the hard mask layer 14 are Al, Cu, Ta, Ti, Zr, nitride (e.g., TiN, TaN, or SiN), and oxide (e.g., SiO₂).

As shown in FIG. 3B, the recording layer 13 is etched by, e.g., milling using the hard mask layer 14.

As shown in FIG. 3C, an insulating film 15′ serving as the sidewall layer 15 having a predetermined thickness T is deposited on the hard mask layer 14 and nonmagnetic insulating layer 12. Examples of the material of the insulating film 15′ are silicon oxide, silicon nitride, and alumina. The insulating film 15′, nonmagnetic insulating layer 12, nonmagnetic metal layer 20, and fixed layer 11 are etched by, e.g., anisotropic etching (e.g., reactive ion etching (RIE)).

As a result, as shown in FIG. 2B, the sidewall layer 15 is formed on the side surfaces of the recording layer 13 and hard mask layer 14. In addition, a first portion 10a of the MTJ element 10 is patterned into a desired shape.

The planar shape of the fixed layer 11 is made larger than that of the recording layer 13 by the barrier stop process. More specifically, as shown in FIG. 2A, side surfaces Sp1 and Sp2 of the fixed layer 11 in the direction of axis of easy magnetization are located outside from side surfaces Sf1 and Sf2 of the recording layer 13 by lengths D1 and D2, respectively, in the direction of axis of easy magnetization. Similarly, side surfaces Sp3 and Sp4 of the fixed layer 11 in the direction of axis of hard magnetization are located outside from side surfaces Sf3 and Sf4 of the recording layer 13 by lengths D3 and D4, respectively, in the direction of axis of hard magnetization. The lengths D1 to D4 are almost the same. Each length almost equals the deposition thickness T of the insulating film 15′ serving as the sidewall layer 15 (FIG. 3C). The deposition thickness T (lengths D1 to D4) of the insulating film 15′ is preferably, e.g., about 5 to 200 nm, i.e., 5 to 200 times the thickness of the nonmagnetic insulating layer 12.

The lengths D1 and D2 in the direction of axis of easy magnetization can be equalized by defining them by the deposition thickness T of the insulating film 15′. For this reason, the recording layer 13 is laid out at the center of the fixed layer 11 in the direction of axis of easy magnetization. Similarly, the lengths D3 and D4 in the direction of axis of hard magnetization can be equalized by defining them by the deposition thickness T of the insulating film 15′. For this reason, the recording layer 13 is laid out at the center of the fixed layer 11 in the direction of axis of hard magnetization.

In the second embodiment, the nonmagnetic metal layer 20 preferably has (f) anti-sidewall formation condition in addition to (a) oxidation resistance, (b) oxygen barrier effect, (c) low sputtering yield, (d) high MR ratio, and (e) wettability described above. That the (f) anti-sidewall formation condition is preferably ensured indicates that the relationship between the nonmagnetic metal layer 20 and the material of the insulating film 15′ serving as the sidewall layer 15 is preferably taken into consideration. For example, if the sidewall layer 15 is formed from alumina or silicon oxide, the nonmagnetic metal layer 20 is preferably made of a material hard to be oxidized. If the side-wall layer 15 is formed from silicon nitride, the nonmagnetic metal layer 20 is preferably made of a material hard to nitride.

According to the second embodiment, the same effect as in the first embodiment can be obtained. Additionally, in the second embodiment, the recording layer 13 is formed by the so-called barrier stop process, and the nonmagnetic insulating layer 12, nonmagnetic metal layer 20, and fixed layer 11 are self-aligned with respect to the recording layer 13. More specifically, the fixed layer 11 whose side surfaces Sp1 to Sp4 are located outside from the side surfaces Sf1 to Sf4 of the recording layer 13 by the thickness T can be formed on the basis of the deposition thickness T of the insulating film 15′. The misalignment between the fixed layer 11 and the recording layer 13 can be suppressed by using the deposition thickness T of the insulating film 15′. Hence, the recording layer 13 can be laid out at the center of the fixed layer 11. Accordingly, the field leakage from the ends of the fixed layer 11 can be prevented from changing due to misalignment in the lithography step. For this reason, the shift amount can more easily be controlled, and the yield and reliability of the MTJ element 10 can be increased.

### Third Embodiment

In an MTJ element according to the third embodiment, another nonmagnetic insulating layer which functions as a tunnel barrier is formed under the nonmagnetic metal layer of the MTJ element according to the second embodiment.

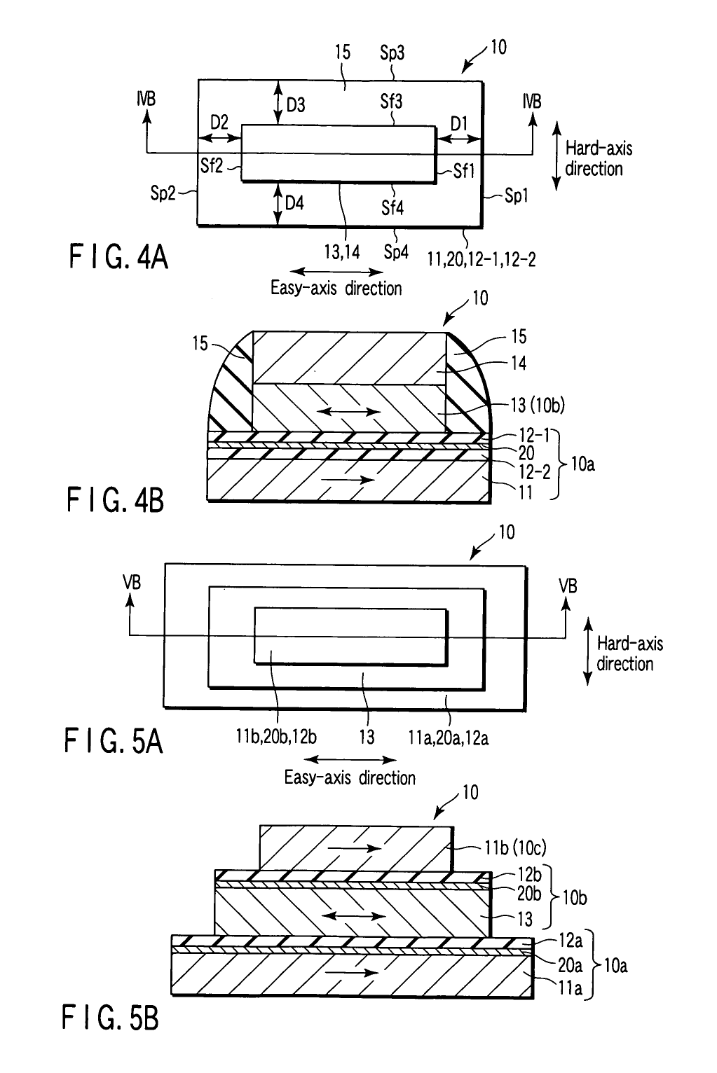

FIGS. 4A and 4B are plan and sectional views, respectively, showing an MTJ element according to the third embodiment of the present invention. The MTJ element according to the third embodiment will be described below.

As shown in FIGS. 4A and 4B, the third embodiment is different from the second embodiment in that a nonmagnetic insulating layer 12-2 is formed between a nonmagnetic metal layer 20 and a fixed layer 11 so that the nonmagnetic metal layer 20 is sandwiched between two nonmagnetic insulating layers 12-1 and 12-2.

According to the third embodiment, the same effect as in the second embodiment can be obtained. Additionally, in the third embodiment, the nonmagnetic insulating layer 12-2 is formed even under the nonmagnetic metal layer 20. With this structure, interdiffusion between the nonmagnetic metal layer (e.g., Pt) 20 and the fixed layer 11 can more reliably be suppressed. For this reason, the heat resistance can be increased, and a more stable element characteristic can be obtained.

The third embodiment can also be applied to the structure of the first embodiment without the sidewall layer 15.

### Fourth Embodiment

An MTJ element according to the fourth embodiment is a modification of the MTJ element according to the first embodiment, in which the single junction structure is changed to a double junction structure.

FIGS. 5A and 5B are plan and sectional views, respectively, showing an MTJ element according to the fourth embodiment of the present invention. The MTJ element according to the fourth embodiment will be described below.

As shown in FIGS. 5A and 5B, an MTJ element 10 having a double junction structure has a first fixed layer 11a serving as a lower ferromagnetic layer, a recording layer 13 serving as an intermediate ferromagnetic layer, a second fixed layer 11b serving as an upper ferromagnetic layer, a first nonmagnetic insulating layer (e.g., tunnel barrier layer) 12a sandwiched between the first fixed layer 11a and the recording layer 13, and a second nonmagnetic insulating layer (e.g., tunnel barrier layer) 12b sandwiched between the second fixed layer 11b and the recording layer 13. In addition, a first nonmagnetic metal layer 20a is formed between the first fixed layer 11a and the first nonmagnetic insulating layer 12a. A second nonmagnetic metal layer 20b is formed between the recording layer 13 and the second nonmagnetic insulating layer 12b.

The MTJ element 10 has a first portion 10a including the first fixed layer 11a, first nonmagnetic metal layer 20a, and first nonmagnetic insulating layer 12a, a second portion 10b including the recording layer 13, second nonmagnetic metal layer 20b, and second nonmagnetic insulating layer 12b, and a third portion 10c including the second fixed layer 11b. The planar shapes of the first fixed layer 11a, first nonmagnetic metal layer 20a, and first nonmagnetic insulating layer 12a included in the first portion 10a are almost the same. Their side surfaces coincide with each other. The planar shapes of the recording layer 13, second nonmagnetic metal layer 20b, and second nonmagnetic insulating layer 12b included in the second portion 10b are almost the same. Their side surfaces coincide with each other. The planar shape of the first portion 10a is larger than that of the second portion 10b. The planar shape of the second portion 10b is larger than that of the third portion 10c.

According to the fourth embodiment, the same effect as in the first embodiment can be obtained. Additionally, in the fourth embodiment, the MTJ element 10 has a double tunnel junction structure. Since the bias voltage per tunnel junction is ½ that of a single tunnel junction structure, the decrease in MR ratio due to the increase in bias voltage can be suppressed.

### Fifth Embodiment

The fifth embodiment is a modification to the fourth embodiment, in which a sidewall layer is formed on the side surfaces of the upper ferromagnetic layer to form the intermediate ferromagnetic layer in a self-aligned manner with respect to the upper ferromagnetic layer. In addition, a sidewall layer is formed on the side surfaces of the intermediate ferromagnetic layer to form the lower ferromagnetic layer in a self-aligned manner with respect to the intermediate ferromagnetic layer.

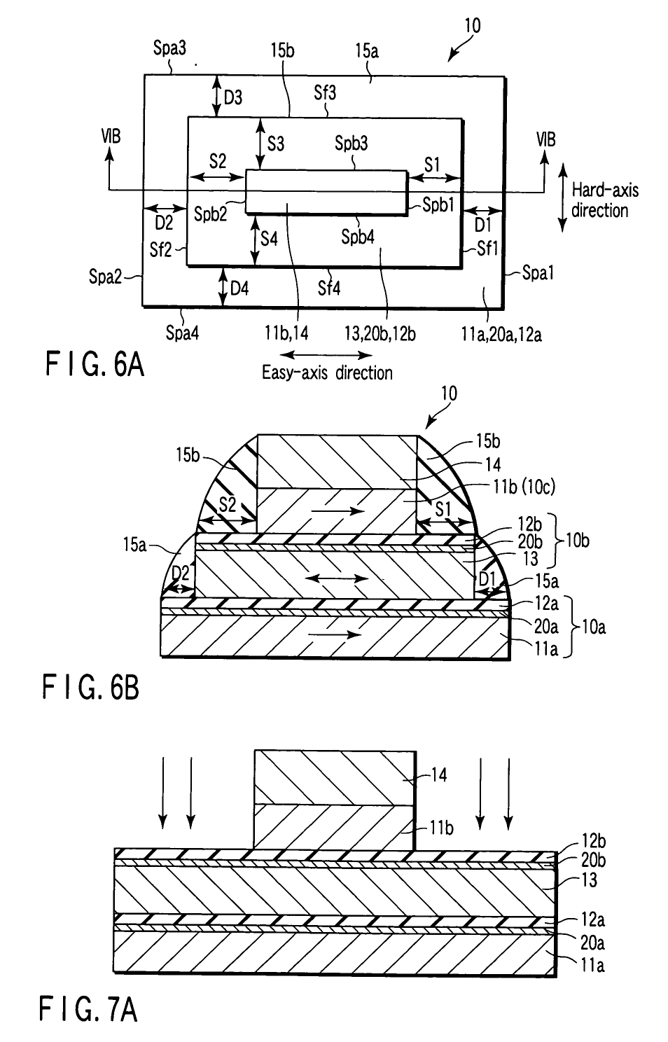

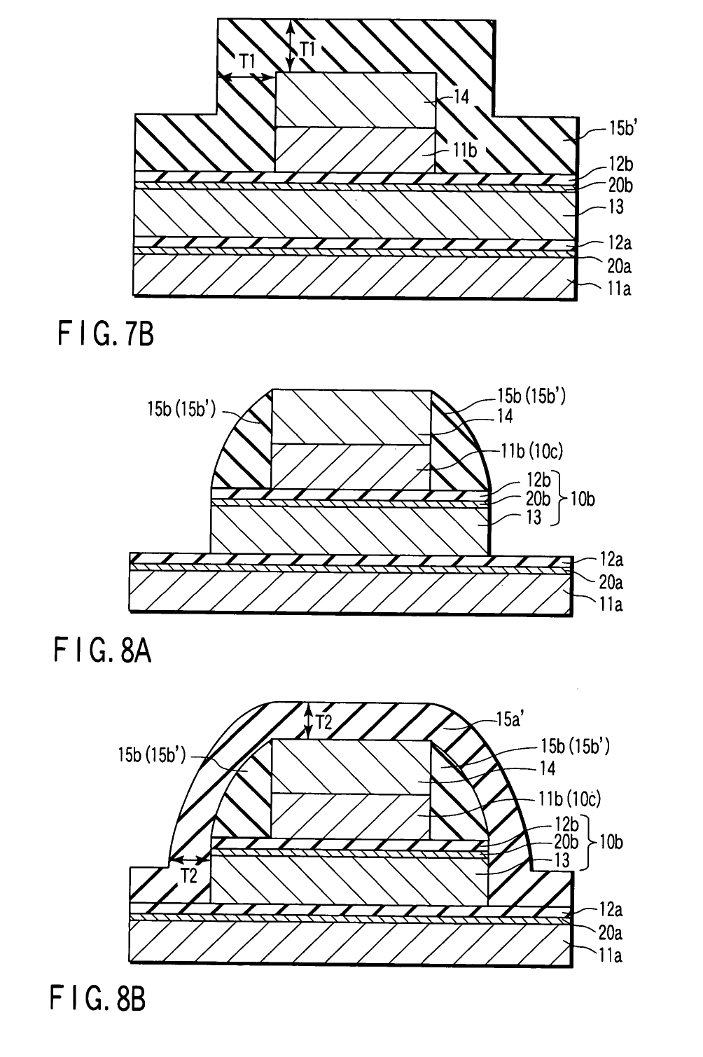

FIGS. 6A and 6B are plan and sectional views, respectively, showing an MTJ element according to the fifth embodiment of the present invention. FIGS. 7A, 7B, 8A, and 8B are sectional views showing steps in manufacturing the MTJ element according to the fifth embodiment of the present invention. The MTJ element according to the fifth embodiment will be described below.

As shown in FIGS. 6A and 6B, the fifth embodiment is different from the fourth embodiment in that a sidewall layer 15b is formed on the side surfaces of a second fixed layer 11b to form a recording layer 13 in a self-aligned manner with respect to the second fixed layer 11b, and a sidewall layer 15a is formed on the side surfaces of the recording layer 13 to form a first fixed layer 11a in a self-aligned manner with respect to the recording layer 13. More specifically, an MTJ element 10 according to the fifth embodiment is formed in the following way.

First, as shown in FIG. 7A, the first fixed layer 11a, first nonmagnetic metal layer 20a, first nonmagnetic insulating layer 12a, recording layer 13, second nonmagnetic metal layer 20b, second nonmagnetic insulating layer 12b, and second fixed layer 11b are sequentially deposited. A hard mask layer 14 having a desired shape is formed on the second fixed layer 11b. Examples of the material of the hard mask layer 14 are Cu, Al, Ta, Ti, Zr, nitride (e.g., TiN, TaN, or SiN), and oxide (e.g., SiO₂). After that, the second fixed layer 11b is etched by, e.g., milling using the hard mask layer 14.

As shown in FIG. 7B, an insulating film 15b′ serving as the sidewall layer 15b having a predetermined thickness T1 is deposited on the hard mask layer 14 and second nonmagnetic insulating layer 12b. Examples of the material of the insulating film 15b′ are silicon oxide, silicon nitride, and alumina. The insulating film 15b′, second nonmagnetic insulating layer 12b, second nonmagnetic metal layer 20b, and recording layer 13 are etched by, e.g., anisotropic etching (e.g., RIE).

As a result, as shown in FIG. 8A, the sidewall layer 15b is formed on the side surfaces of the second fixed layer 11b and hard mask layer 14. In addition, a second portion 10b of the MTJ element 10 is fabricated into a desired shape.

Next, as shown in FIG. 8B, an insulating film 15a′ serving as the sidewall layer 15a having a predetermined thickness T2 is deposited on the hard mask layer 14, sidewall layer 15b, and first nonmagnetic insulating layer 12a. Examples of the material of the insulating film 15a′ are silicon oxide, silicon nitride, and alumina. The material of the insulating film 15a′ and that of the insulating film 15b′ can be the same or different. The insulating film 15a′, first nonmagnetic insulating layer 12a, first nonmagnetic metal layer 20a, and first fixed layer 11a are etched by, e.g., anisotropic etching (e.g., RIE).

As a result, as shown in FIG. 6B, the sidewall layer 15a is formed on the side surfaces of a first portion 10a. In addition, the first portion 10a of the MTJ element 10 is fabricated into a desired shape.

The planar shape of the first fixed layer 11a is made larger than that of the recording layer 13 by the barrier stop process. In addition, the planar shape of the recording layer 13 is larger than that of the second fixed layer 11b.

More specifically, as shown in FIG. 6A, side surfaces Spa1 and Spa2 of the first fixed layer 11a in the direction of axis of easy magnetization are located outside from side surfaces Sf1 and Sf2 of the recording layer 13 by lengths D1 and D2, respectively, in the direction of axis of easy magnetization. Similarly, side surfaces Spa3 and Spa4 of the first fixed layer 11a in the direction of axis of hard magnetization are located outside from side surfaces Sf3 and Sf4 of the recording layer 13 by lengths D3 and D4, respectively, in the direction of axis of hard magnetization.

In addition, the side surfaces Sf1 and Sf2 of the recording layer 13 in the direction of axis of easy magnetization are located outside from side surfaces Spb1 and Spb2 of the second fixed layer 11b by lengths S1 and S2, respectively, in the direction of axis of easy magnetization. Similarly, the side surfaces Sf3 and Sf4 of the recording layer 13 in the direction of axis of hard magnetization are located outside from side surfaces Spb3 and Spb4 of the second fixed layer 11b by lengths S3 and S4, respectively, in the direction of axis of easy magnetization.

The lengths D1 to D4 are almost the same. Each length almost equals the deposition thickness T2 of the insulating film 15a′ serving as the sidewall layer 15a (FIG. 7B). The deposition thickness T2 (lengths D1 to D4) of the insulating film 15a′ is preferably, e.g., about 5 to 200 nm, i.e., 5 to 200 times the thickness of the second nonmagnetic insulating layer 12b.

The lengths S1 to S4 are almost the same. Each length almost equals the deposition thickness T1 of the insulating film 15b′ serving as the sidewall layer 15b (FIG. 8B). The deposition thickness T1 (lengths S1 to S4) of the insulating film 15b′ is preferably, e.g., about 5 to 200 nm, i.e., 5 to 200 times the thickness of the first nonmagnetic insulating layer 12a.

The lengths D1 and D2 in the direction of axis of easy magnetization can be equalized by defining them by the deposition thickness T2 of the insulating film 15a′. For this reason, the recording layer 13 is laid out at the center of the first fixed layer 11a in the direction of axis of easy magnetization. Similarly, the lengths D3 and D4 in the direction of axis of hard magnetization can be equalized by defining them by the deposition thickness T2 of the insulating film 15a′. For this reason, the recording layer 13 is laid out at the center of the first fixed layer 11a in the direction of axis of hard magnetization.

The lengths S1 and S2 in the direction of axis of easy magnetization can be equalized by defining them by the deposition thickness T1 of the insulating film 15b′. For this reason, the second fixed layer 11b is laid out at the center of the recording layer 13 in the direction of axis of easy magnetization. Similarly, the lengths S3 and S4 in the direction of axis of hard magnetization can be equalized by defining them by the deposition thickness T1 of the insulating film 15b′. For this reason, the second fixed layer 11b is laid out at the center of the recording layer 13 in the direction of axis of hard magnetization.

According to the fifth embodiment, the same effect as in the fourth embodiment can be obtained. Additionally, the misalignment between the first fixed layer 11a and the recording layer 13 can be suppressed by using the deposition thickness T2 of the insulating film 15a′. Hence, the recording layer 13 can be laid out at the center of the first fixed layer 11a. Similarly, the misalignment between the second fixed layer 11b and the recording layer 13 can be suppressed by using the deposition thickness T1 of the insulating film 15b′. Hence, the second fixed layer 11b can be laid out at the center of the recording layer 13. Accordingly, the field leakage from the ends of the first fixed layer 11a or recording layer 13 can be prevented from changing due to misalignment in the lithography step. For this reason, the shift amount can easily be controlled, and the yield and reliability of the MTJ element 10 can be increased.

### Sixth Embodiment

In an MTJ element according to the sixth embodiment, another nonmagnetic insulating layer which functions as a tunnel barrier is formed under the nonmagnetic metal layer of the MTJ element according to the fifth embodiment.

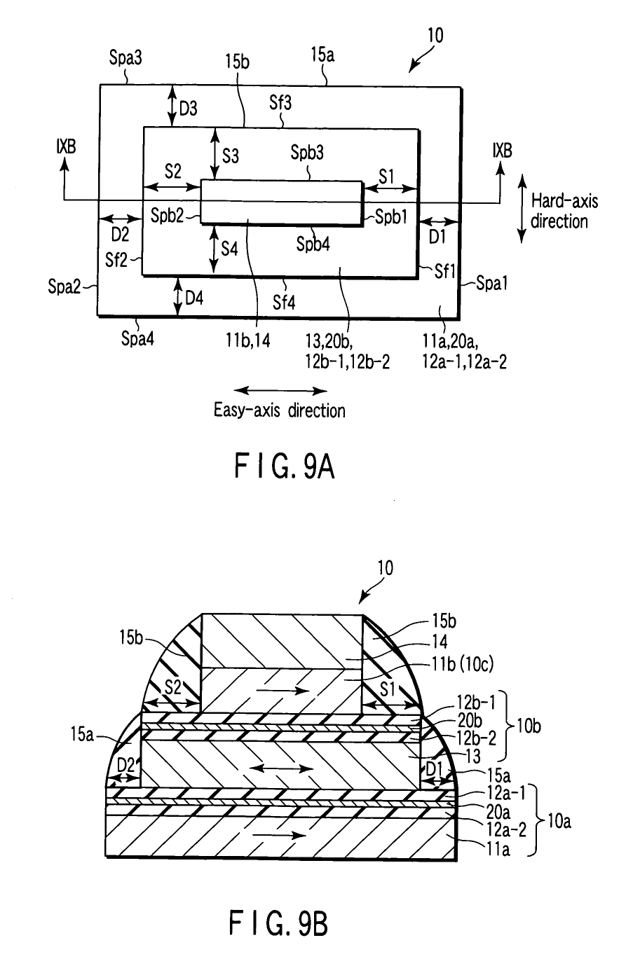

FIGS. 9A and 9B are plan and sectional views, respectively, showing an MTJ element according to the sixth embodiment of the present invention. The MTJ element according to the sixth embodiment will be described below.

As shown in FIGS. 9A and 9B, the sixth embodiment is different from the fifth embodiment in that a nonmagnetic insulating layer 12a-2 is formed between a first nonmagnetic metal layer 20a and a first fixed layer 11a so that the first nonmagnetic metal layer 20a is sandwiched between two nonmagnetic insulating layers 12a-1 and 12a-2. In addition, a nonmagnetic insulating layer 12b-2 is formed between a second nonmagnetic metal layer 20b and a recording layer 13 so that the second nonmagnetic metal layer 20b is sandwiched between two nonmagnetic insulating layers 12b-1 and 12b-2.

According to the sixth embodiment, the same effect as in the fifth embodiment can be obtained. Additionally, in the sixth embodiment, the nonmagnetic insulating layer 12a-2 is formed even under the nonmagnetic metal layer 20a, and the nonmagnetic insulating layer 12b-2 is formed even under the nonmagnetic metal layer 20b. With this structure, interdiffusion between the nonmagnetic metal layer (e.g., Pt) 20a and the fixed layer 11a and interdiffusion between the nonmagnetic metal layer (e.g., Pt) 20b and the recording layer 13 can more reliably be suppressed. For this reason, the heat resistance can be increased, and a more stable element characteristic can be obtained.

The sixth embodiment can also be applied to the structure of the fourth embodiment without the sidewall layers 15a and 15b. The nonmagnetic insulating layer need not always be formed under both of the first and second nonmagnetic metal layers 20a and 20b. The nonmagnetic insulating layer can also be formed under only one of the first and second nonmagnetic metal layers 20a and 20b.

### Seventh Embodiment

In the seventh embodiment, a magnetic random access memory in which an MTJ element 10 according to one of the above embodiments is used as a memory element, and a plurality of MTJ elements are laid out in an array will be described. As examples of the memory cell structure, (a) select transistor cell, (b) select diode cell, (c) cross-point cell, and (d) toggle cell will be described below.

(a) Select Transistor

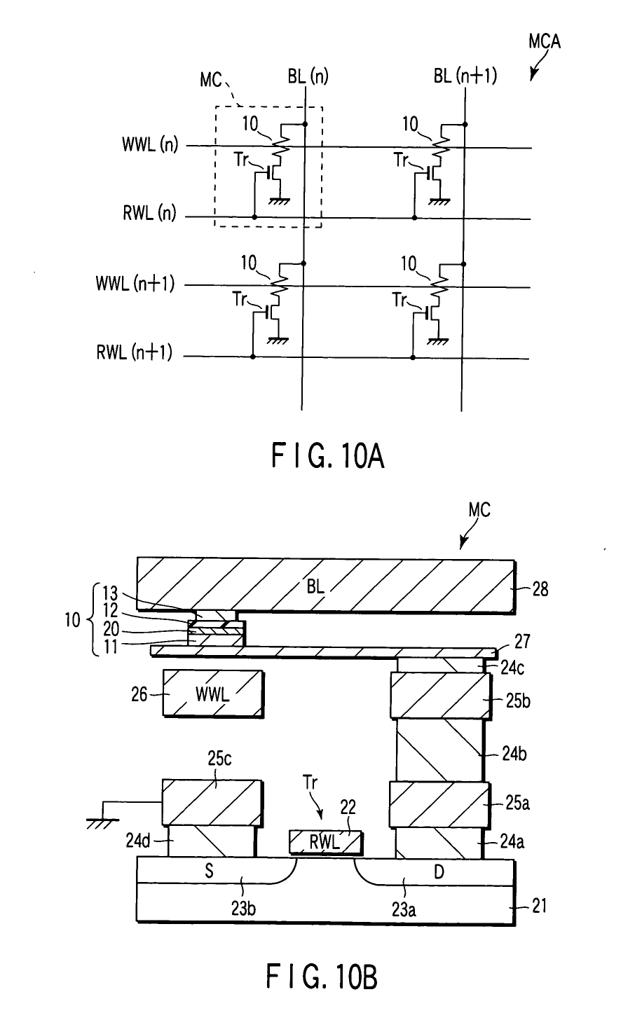

FIGS. 10A and 10B show a select transistor memory cell of a magnetic random access memory according to the seventh embodiment of the present invention. The select transistor cell structure will be described below.

As shown in FIGS. 10A and 10B, one cell MC having a select transistor structure includes one MTJ element 10, transistor (e.g., MOS transistor) Tr connected to the MTJ element, bit line (BL) 28, and word line (WWL) 26. A memory cell array MCA is formed by laying out a plurality of memory cells MC in an array.

More specifically, one terminal of the MTJ element 10 is connected to one end (drain diffusion layer) 23a of the current path of the transistor Tr through a base metal layer 27, contacts 24a, 24b, and 24c, and wirings 25a and 25b. The other terminal of the MTJ element 10 is connected to the bit line 28. The write word line 26 electrically disconnected from the MTJ element 10 is arranged under the MTJ element 10. The other end (source diffusion layer) 23b of the current path of the transistor Tr is connected to, e.g., ground through a contact 24d and wiring 25c. A gate electrode 22 of the transistor Tr functions as a read word line (RWL).

One terminal of the MTJ element 10 on the side of the base metal layer 27 is, e.g., a fixed layer 11. The other terminal of the MTJ element 10 on the side of the bit line 28 is, e.g., a recording layer 13. This arrangement may be reversed. In addition, for example, a hard mask layer 14 may be inserted between the MTJ element 10 and the bit line 28. The MTJ element 10 can be laid out while setting the direction of axis of easy magnetization along the running direction of the bit line 28 or along the running direction of the word line 26.

In the select transistor memory cell, the data write and read are executed in the following way.

The write operation is executed in the following way. The write word line 26 and bit line 28 corresponding to a selected one of the plurality of MTJ elements 10 are selected. When write currents Iw1 and Iw2 are supplied to the selected write word line 26 and bit line 28, a synthetic field H created by the write currents Iw1 and Iw2 is applied to the MTJ element 10. Accordingly, the magnetization of the recording layer 13 of the MTJ element 10 is reversed to create a state in which the magnetization directions of the fixed layer 11 and recording layer 13 are parallel or anti-parallel. For example, when the parallel state is defined as a “1” state, and the anti-parallel state is defined as a “0” state, a binary data write is implemented.

The read operation is executed in the following way by using the transistor Tr which functions as a read switching element. The bit line 28 and read word line (RWL) corresponding to the selected MTJ element 10 are selected. A read current Ir which tunnels the nonmagnetic insulating layer 12 of the MTJ element 10 is supplied. The junction resistance value changes in proportion to the cosine of the relative angle of the magnetizations of the fixed layer 11 and recording layer 13. When the magnetization of the MTJ element 10 is in the parallel state (e.g., “1” state), the resistance is low. In the anti-parallel state (e.g., “0” state), the resistance is high. That is, a tunneling magnetoresistive (TMR) effect is obtained. The “1” or “0” state of the MTJ element 10 is determined by reading the difference in resistance value.

(b) Select Diode

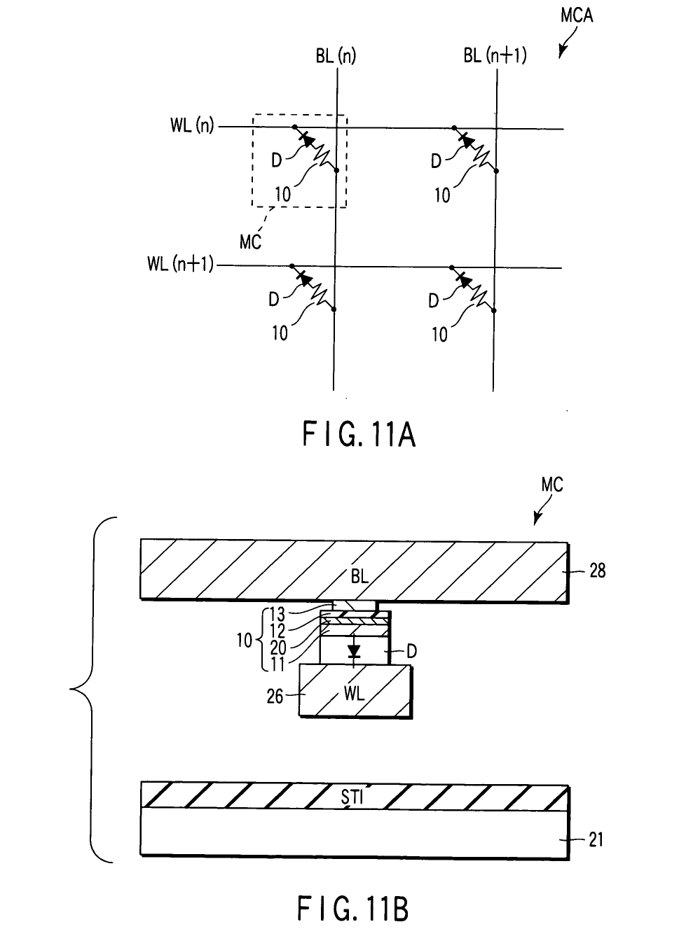

FIGS. 11A and 11B show a select diode memory cell of the magnetic random access memory according to the seventh embodiment of the present invention. The select diode cell structure will be described below.

As shown in FIGS. 11A and 11B, one cell MC having a select diode structure includes one MTJ element 10, a diode D connected to the MTJ element, the bit line (BL) 28, and the word line (WL) 26. The memory cell array MCA is formed by laying out a plurality of memory cells MC in an array.

The diode D is, e.g., a p-n junction diode including a p-type semiconductor layer and n-type semiconductor layer. One terminal (e.g., p-type semiconductor layer) of the diode D is connected to the MTJ element 10. The other terminal (e.g., n-type semiconductor layer) of the diode D is connected to the word line 26. In the structure shown in FIGS. 11A and 11B, a current flows from the bit line 28 to the word line 26.

The location or direction of the diode D can be changed variously. For example, the diode D may be arranged in a direction to supply a current from the word line 26 to the bit line 28. The diode D may be formed in a semiconductor substrate 21. The diode D may be a Schottky barrier diode including a semiconductor layer and metal layer.

The data write operation of the select diode memory cell is the same as that of the select transistor cell. The write currents Iw1 and Iw2 are supplied to the bit line 28 and word line 26 to set the magnetization of the MTJ element 10 in the parallel or anti-parallel state.

The data read operation is also almost the same as that of the select transistor cell. In the select diode cell, the diode D is used as a read switching element. More specifically, the biases of the bit line 28 and word line 26 are controlled by using the rectifying effect of the diode D such that an unselected MTJ element has a reverse bias. Accordingly, the read current Ir is supplied to only the selected MTJ element 10.

(c) Cross-Point

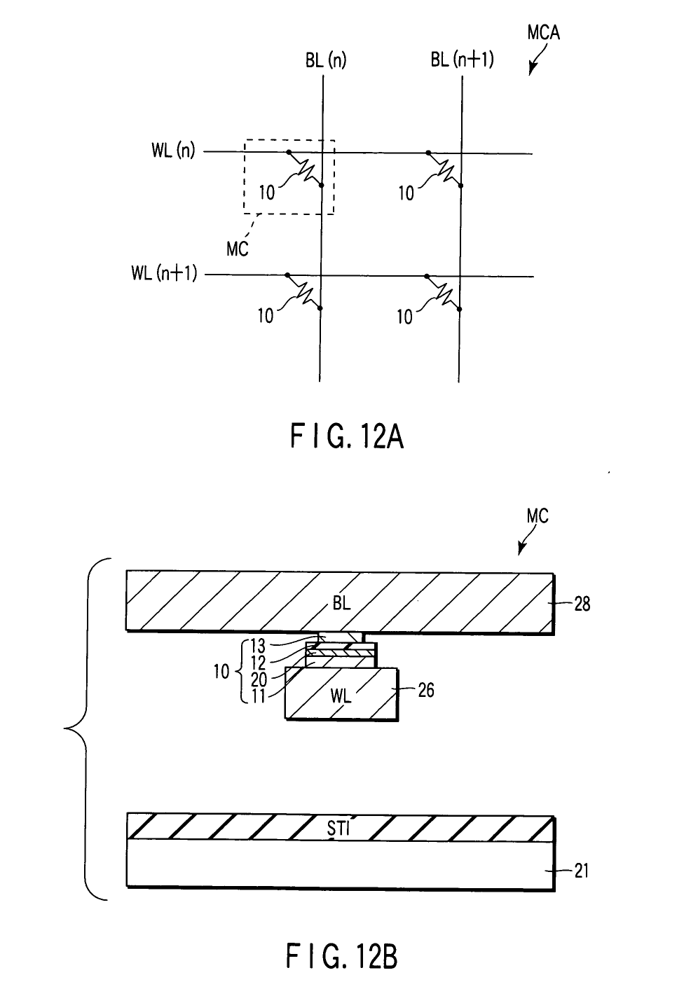

FIGS. 12A and 12B show a cross-point memory cell of the magnetic random access memory according to the seventh embodiment of the present invention. The cross-point cell structure will be described below.

As shown in FIGS. 12A and 12B, one cell MC having a cross-point structure includes one MTJ element 10, bit line 28, and word line 26. The memory cell array MCA is formed by laying out a plurality of memory cells MC in an array.

More specifically, the MTJ element 10 is arranged near the intersection between the bit line 28 and the word line 26. One terminal of the MTJ element 10 is connected to the word line 26. The other terminal of the MTJ element 10 is connected to the bit line 28.

The data write operation of the cross-point memory cell is the same as that of the select transistor cell. The write currents Iw1 and Iw2 are supplied to the bit line 28 and word line 26 to set the magnetization of the MTJ element 10 in the parallel or anti-parallel state. In the data read operation, the read current Ir is supplied to the bit line 28 and word line 26 connected to the selected MTJ element 10, thereby reading out the data of the MTJ element 10.

(d) Toggle

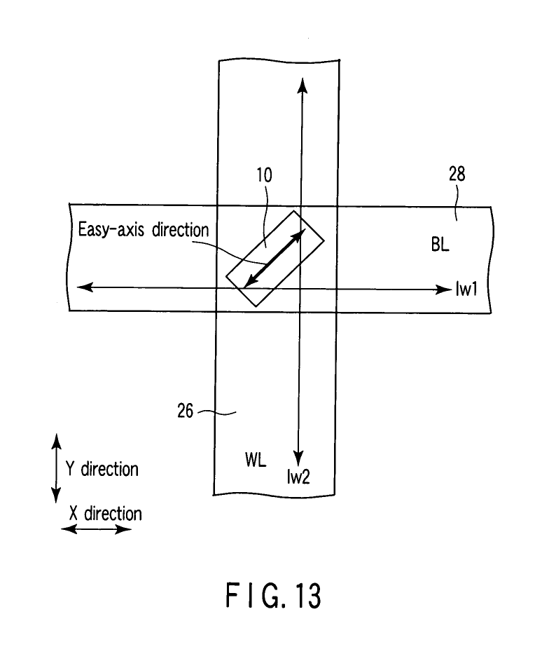

FIG. 13 is a plan view showing a toggle memory cell of the magnetic random access memory according to the seventh embodiment of the present invention. The toggle cell structure will be described below.

As shown in FIG. 13, in the toggle cell, the MTJ element 10 is laid out such that its axis of easy magnetization is tilted with respect to the running direction (X direction) of the bit line 28 or the running direction (Y direction) of the word line 26, i.e., with respect to the direction of write current Iw1 to be supplied to the bit line 28 or the direction of write current Iw2 to be supplied to the word line 26. The tilt of the MTJ element 10 is, e.g., 30° to 60°, and preferably, 45°.

In the toggle memory cell, the data write and read are executed in the following way.

The write operation is executed in the following way. In a toggle write, before arbitrary data is written in a selected cell, the data of the selected cell is read out. If it is determined by reading out the data of the selected cell that the arbitrary data has already been written, no write is executed. If data different from the arbitrary data has been written, the write is executed to rewrite the data.

After the above-described confirmation cycle, if data must be written in the selected cell, two write wirings (bit line 28 and word line 26) are sequentially turned on. The write wiring which has been turned on first is turned off first. Then, the write wiring which has been turned on later is turned off. For example, the procedures include four cycles: the word line 26 is turned on to supply the write current Iw2→the bit line 28 is turned on to supply the write current Iw1→the word line 26 is turned off to stop supplying the write current Iw2→the bit line 28 is turned off to stop supplying the write current Iw1.

In the data read operation, the read current Ir is supplied to the bit line 28 and word line 26 connected to the selected MTJ element 10, thereby reading out the data of the MTJ element 10.

The present invention is not limited to the above embodiments, and various changes and modifications can be made within the spirit and scope of the present invention.

For example, in the single junction structure, the locations of the fixed layer 11 and recording layer 13 may be reversed so that the recording layer 13 functions as the lower ferromagnetic layer, and the fixed layer 11 functions as the upper ferromagnetic layer.

In the MTJ element 10, at least one of the fixed layer 11 and recording layer 13 can have an anti-ferromagnetic coupling structure or ferromagnetic coupling structure. In the anti-ferromagnetic coupling structure, interlayer exchange coupling occurs such that the magnetization directions of two ferromagnetic layers which sandwich the nonmagnetic layer are anti-parallel. In the ferromagnetic coupling structure, interlayer exchange coupling occurs such that the magnetization directions of two ferromagnetic layers which sandwich the nonmagnetic layer are parallel.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A magnetic random access memory in which a plurality of magnetoresistive elements are laid out in an array,
the magnetoresistive element comprising:
a lower ferromagnetic layer;
an upper ferromagnetic layer which has a planar shape smaller than a planar shape of the lower ferromagnetic layer;
a first nonmagnetic insulating layer which is formed between the lower ferromagnetic layer and the upper ferromagnetic layer; and
a first nonmagnetic metal layer which is formed between the first nonmagnetic insulating layer and the upper ferromagnetic layer.

2. The memory according to claim 1, wherein the first nonmagnetic metal layer contains a material which is harder to be oxidized than the first nonmagnetic insulating layer.

3. The memory according to claim 1, wherein the first nonmagnetic metal layer contains a material which is harder to be oxidized than the lower ferromagnetic layer.

4. The memory according to claim 1, wherein the first nonmagnetic metal layer contains a material made of atoms heavier than the lower ferromagnetic layer.

5. The memory according to claim 1, wherein the first nonmagnetic metal layer contains a material having an oxygen barrier effect.

6. The memory according to claim 1, wherein the first nonmagnetic metal layer is essentially formed from a material containing one of Pt, Ir, and Cu.

7. The memory according to claim 1, wherein the first nonmagnetic metal layer has a thickness of 0.3 to 2.0 nm.

8. The memory according to claim 1, wherein planar shapes of the first nonmagnetic metal layer and the first nonmagnetic insulating layer are almost the same as the planar shape of the lower ferromagnetic layer.

9. The memory according to claim 1, further comprising a sidewall layer which is formed on side surfaces of the upper ferromagnetic layer.

10. The memory according to claim 9, wherein
side surfaces of the lower ferromagnetic layer are located outside from the side surfaces of the upper ferromagnetic layer, and
a length from the side surface of the upper ferromagnetic layer to the side surface of the lower ferromagnetic layer substantially equals a thickness of the sidewall layer.

11. The memory according to claim 9, wherein a thickness of the sidewall layer is 5 to 200 times a thickness of the first nonmagnetic insulating layer.

12. The memory according to claim 1, wherein the magnetoresistive element further comprises a second nonmagnetic insulating layer which is formed between the lower ferromagnetic layer and the first nonmagnetic metal layer.

13. The memory according to claim 1, further comprising
an intermediate ferromagnetic layer which is formed between the lower ferromagnetic layer and the upper ferromagnetic layer and has a planar shape smaller than the planar shape of the lower ferromagnetic layer and larger than the planar shape of the upper ferromagnetic layer,
a second nonmagnetic metal layer which is formed between the intermediate ferromagnetic layer and the upper ferromagnetic layer, and
a second nonmagnetic insulating layer which is formed between the second nonmagnetic metal layer and the upper ferromagnetic layer.

14. The memory according to claim 13, further comprising
a first sidewall layer which is formed on side surfaces of the intermediate ferromagnetic layer, the second nonmagnetic metal layer, and the second non-magnetic insulating layer, and
a second sidewall layer which is formed on side surfaces of the upper ferromagnetic layer.

15. The memory according to claim 14, wherein
side surfaces of the lower ferromagnetic layer are located outside from the side surfaces of the intermediate ferromagnetic layer,
a length from the side surface of the intermediate ferromagnetic layer to the side surface of the lower ferromagnetic layer substantially equals a thickness of the first sidewall layer,
side surfaces of the intermediate ferromagnetic layer are located outside from the side surfaces of the upper ferromagnetic layer, and
a length from the side surface of the upper ferromagnetic layer to the side surface of the intermediate ferromagnetic layer substantially equals a thickness of the second sidewall layer,

16. The memory according to claim 13, wherein the magnetoresistive element further comprises
a third nonmagnetic insulating layer which is formed between the lower ferromagnetic layer and the first nonmagnetic metal layer, and
a fourth nonmagnetic insulating layer which is formed between the intermediate ferromagnetic layer and the second nonmagnetic metal layer.

17. The memory according to claim 1, further comprising
one of a bit line and a word line which is connected to one terminal of the magnetoresistive element, and
a switching element which is connected to the other terminal of the magnetoresistive element.

18. The memory according to claim 17, further comprising
a write word line which is electrically disconnected from the magnetoresistive element and to which a write current is supplied to record information in the magnetoresistive element.

19. The memory according to claim 1, further comprising
a bit line which is connected to one terminal of the magnetoresistive element, and
a word line which is connected to the other terminal of the magnetoresistive element.

20. The memory according to claim 1, further comprising a first write wiring and a second write wiring which sandwich the magnetoresistive element, and
a direction of axis of easy magnetization of the magnetoresistive element is tilted with respect to a running direction of one of the first write wiring and the second write wiring by 30° to 60°.
